(19) United States
(12) Patent Application Publication
(10) Pub. No.: US 2011/0007590 A1
(43) Pub. Date: Jan. 13, 2011

(54) SEMICONDUCTOR STORAGE DEVICE AND METHOD OF CONTROLLING WORD LINE POTENTIAL

(75) Inventor: Akira KATAYAMA, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/834,781

(22) Filed: Jul. 12, 2010

(30) Foreign Application Priority Data
Jul. 10, 2009 (JP) 2009-163947

(51) Int. Cl. G11C 7/00; G11C 8/08

(52) U.S. Cl. 365/203; 365/230.06; 365/156

(57) ABSTRACT

According to one embodiment, a semiconductor storage device includes a memory cell array, word lines, a driver, and a word-line-potential control circuit. In the memory cell array, memory cells are arranged in a matrix shape in a row direction and a column direction. The word lines perform row selection for the memory cell array during readout of data. The driver drives the word lines. The word-line-potential control circuit controls potential of the word lines such that, during the readout of data, gradient of rising of potential of the word lines to first potential is larger than gradient of further rising of the potential from the first potential to second potential.

### CROSS-REFERENCE TO RELATED APPLICATIONS

This application is based upon and claims the benefit of priority from the prior Japanese Patent Application No. 2009-163947, filed on Jul. 10, 2009; the entire contents of which are incorporated herein by reference.

### FIELD

Embodiments described herein relate generally to a semiconductor storage device and a method of controlling word line potential.

### BACKGROUND

According to the increase in a degree of integration and the reduction in power supply voltage of a semiconductor integrated circuit, in some case, a disturb margin during readout of data from an SRAM decreases and data of memory cells is destroyed. As an effective method for preventing the destruction of the data of the memory cells during the readout of data from the SRAM, there is a method of reducing a through rate of word line potential. However, an operating frequency falls in this method.

On the other hand, Japanese Patent Application Laid-Open No. 2006-40466 discloses a method of holding, to improve stability without delaying access time or increasing a cell area, the potential of word lines WL at first potential lower than second potential for a predetermined period during readout of data from an SRAM and raising the potential to the second potential after the gate voltage of an access transistor falls.

However, in the method disclosed in Japanese Patent Application Laid-Open No. 2006-40466, because the potential of a storage node is stabilized at the first potential and amplified and then raised to the second potential, the operating frequency falls for the period in which the potential is held at the first potential.

### BRIEF DESCRIPTION OF THE DRAWINGS

FIG. 1 is a block diagram of the schematic configuration of a semiconductor storage device according to a first embodiment of the present invention;

FIG. 2 is a block diagram of the schematic configurations of a driver 15 and a word-line-potential control circuit 21 shown in FIG. 1;

FIG. 3 is a timing chart of signal waveforms of units shown in FIG. 2;

FIG. 4 is a graph of a waveform of the potential of a word lines WL shown in FIG. 1 during readout of data;

FIGS. 5A and 5B are graphs of simulation waveforms of the potentials of storage nodes n and nb shown in FIG. 1 during the readout of data compared with an example in the past;

FIGS. 6A to 6C are diagrams of changes in a Z value that occur when first rising time T1 and first rising voltage V1 shown in FIG. 4 are changed;

FIGS. 7A and 7B are enlarged diagrams of a part of FIG. 6C;

FIG. 8 is a diagram of changes in the Z value that occur when a through rate S/R is changed;

FIG. 9 is a graph of a relation between power supply voltage and operation time and percentage defectives during the readout of data;

FIG. 10 is a block diagram of the schematic configuration of a semiconductor storage device according to a second embodiment of the present invention;

FIG. 11 is a block diagram of the schematic configurations of the driver 15 and the word-line-potential control circuit 31 shown in FIG. 10; and

FIG. 12 is a timing chart of signal waveforms of units shown in FIG. 11.

### DETAILED DESCRIPTION

Exemplary embodiments of a semiconductor storage device and a word line potential will be explained below in detail with reference to the accompanying drawings. The present invention is not limited to the following embodiments.

A semiconductor storage device according to an embodiment of the present invention includes a memory cell array, word lines, a driver, and a word-line-potential control circuit. In the memory cell array, memory cells are arranged in a matrix shape in a row direction and a column direction. The word lines perform row selection for the memory cell array during readout of data. The driver drives the word lines. The word-line-potential control circuit controls the potential of the word lines such that, during the readout of data, gradient of rising of the potential of the word lines to first potential is larger than gradient of further rising of the potential from the first potential to second potential.

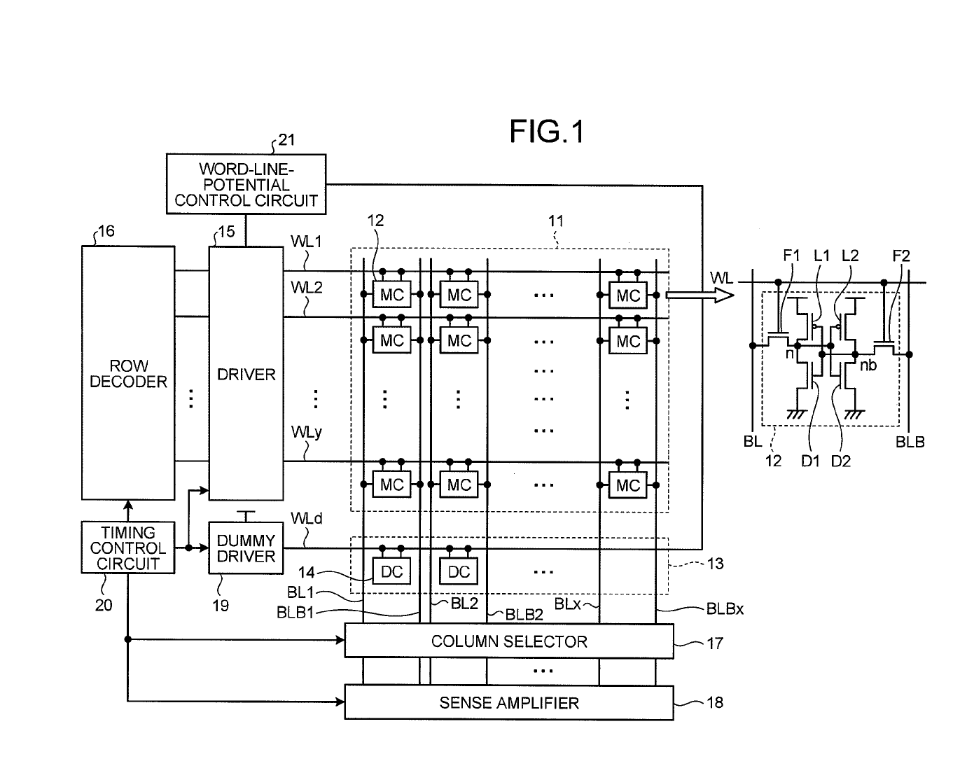

FIG. 1 is a block diagram of the schematic configuration of a semiconductor storage device according to a first embodiment of the present invention.

In FIG. 1, the semiconductor storage device includes a memory cell array 11, a dummy cell array 13, a driver 15, a dummy driver 19, a row decoder 16, a column selector 17, a sense amplifier 18, a timing control circuit 20, and a word-line-potential control circuit 21.

In the memory cell array 11, memory cells 12 are arranged in a matrix shape in a row direction and a column direction. The memory cell array 11 includes word lines WL1 to WLy (y is an integer equal to or larger than 2) that perform row selection for the memory cell array 11. The memory cell array 11 also includes bit lines BL1 to BLx and BLB1 to BLBx (x is an integer equal to or larger than 2).

Each of the memory cells 12 includes a pair of driving transistors D1 and D2, a pair of load transistors L1 and L2, and a pair of transfer transistors F1 and F2. As the load transistors L1 and L2, a P-channel field effect transistor can be used. As the transfer transistors F1 and F2, an N-channel field effect transistor can be used.

The driving transistor D1 and the load transistor L1 connected in series to each other and the driving transistor D2 and the load transistor L2 are connected to each other to configure CMOS inverters. Outputs and inputs of the pair of CMOS inverters are cross-coupled to each other to configure a flip-flop.

Any one word line WL among the word lines WL1 to WLy is connected to gates of the transfer transistors F1 and F2.

Any one bit line BL among the bit lines BL1 to BLx is connected to a gate of the driving transistor D2, a gate of the load transistor L2, a drain of the driving transistor D1, and a drain of the load transistor L1 via the transfer transistor F1. Any one bit line BLB among the bit lines BLB1 to BLBx is connected to a drain of the driving transistor D2, a drain of the load transistor L2, a gate of the driving transistor D1, and a gate of the load transistor L1 via the transfer transistor F2. A connection point of the drain of the driving transistor D1 and the drain of the load transistor L1 can form a storage node n. A connection point of the drain of the driving transistor D2 and the drain of the load transistor L2 can form a storage node nb.

In the dummy cell array 13, dummy cells 14 are arranged in the row direction. A dummy cell array 13 includes a dummy word line WLd that performs selection of the dummy cells 14. The dummy cells 14 can be configured in the same manner as the memory cells 12. The dummy cells 14 are connected to the dummy word line WLd. The bit lines BL1 to BLx and BLB1 to BLBx can be configured not to be connected to the dummy cells. 14.

The parasitic capacitance of the dummy word line WLd is set smaller than the parasitic capacitance of any one word line WL among the word lines WL1 to WLy. For example, the number of dummy cells 14 connected to the dummy word line WLd is set smaller than the number of memory cells 12 connected to any one word line WL among the word lines WL1 to WLy.

The driver 15 can separately drive the word lines WL1 to WLy. For example, the driver 15 can include an inverters provided in each of the respective word lines WL1 to WLy.

The dummy driver 19 can drive the dummy word line WLd at timing same as timing for the driving of any one word line WL among the word lines WL1 to WLy.

The row decoder 16 can select the word lines WL1 to WLy caused to perform row selection for the memory cell array 11 and cause the driver 15 to drive the selected word lines WL1 to WLy.

The column selector 17 can select the bit lines BL1 to BLx and BLB1 to BLBx caused to perform column selection for the memory cell array 11.

The sense amplifier 18 can amplify signals read out from the memory cells 12 onto the bit lines BL1 to BLx and BLB1 to BLBx.

The timing control circuit 20 can control readout timing of data from the memory cells 12 and writing timing of data in the memory cells 12.

The word-line-potential control circuit 21 can control potential Vwl of the word lines WL such that, during readout of data from the memory cells 12, gradient of rising of the potential Vwl of the word lines WL to first potential V1 is larger than gradient of further rising of the potential Vwl from the first potential V1 to the second potential V2. The word-line-potential control circuit 21 can control rising gradient of the potential Vwl of the word lines WL by controlling driving force of an electric power for the driver 15. The first potential V1 can be set to, for example, threshold voltage of the transfer transistors F1 and F2. The second potential V2 can be set to a fixed value for reading out data from the memory cells 12 and can be set to, for example, power supply potential.

When data is read out from a selected cell, the column selector 17 performs column selection. The selected bit lines BL1 to BLx and BLB1 to BLBx are pre-charged. The row decoder 16 performs row selection. The driver 15 drives selected word lines WL1 to WLy. The dummy driver 19 drives the dummy word line WLd.

When the selected word lines WL1 to WLy are driven by the driver 15, the potential Vwl of the word lines WL1 to WLy rises according to the driving force of power supply to the driver 15 controlled by the word-line-potential control circuit 21. When the dummy word line WLd is driven by the dummy driver 19, potential Vwld of the word lines WL1 to WLy rises to the first potential V1 according to the driving force of the dummy driver 19.

The parasitic capacitance of the dummy word line WLd is smaller than the parasitic capacitance of the word lines WL1 to WLy. Therefore, the potential Vwld of the dummy word line WLd rises quicker than the potential Vwl of the word lines WL1 to WLy.

When the potential Vwld of the dummy word line WLd rises quicker than the potential Vwl of the selected word lines WL1 to WLy, the word-line-potential control circuit 21 reduces the driving force of the power supply to the driver 15 when the potential Vwl of the word lines WL1 to WL2 rises to the first potential V1. When the driving force of the power supply to the driver 15 is reduced by the word-line-potential control circuit 21, the potential Vwl of the word lines WL1 to WLy further rises from the first potential V1 to the second potential V2 at gradient smaller than gradient at which the potential Vwl of the word lines WL1 to WLy rises to the first potential V1.

When the potential Vwl of the word lines WL1 to WLy further rises to the second potential V2, the transfer transistors F1 and F2 enter a saturated region and the storage nodes n and nb conduct with the bit lines BL1 to BLx and BLB1 to BLBx. When the storage nodes n and nb conduct with the bit lines BL1 to BLx and BLB1 to BLBx, the potentials of the bit lines BL1 to BLx and BLB1 to BLBx change according to the potentials of the storage nodes n and nb and are amplified by the sense amplifier 18.

For example, it is assumed that the potential of the storage node n is at a low level and a potential of the storage node nb is at a high level. The bit lines BL and BLB are pre-charged during readout of data from a selected cell. Therefore, the potentials of the bit lines BL and BLB change to the high level. When the transfer transistors F1 and F2 suddenly enter the saturated region during the readout of data from the selected cell, the potential of the storage node n is suddenly raised from the low level to the high level and a rise in the potential of the storage node n at that point increases. When the rise in the potential of the storage node n during the readout of data from the selected cell increases to be equal to or larger than a certain degree, the potentials of the storage nodes n and nb are inverted and the potential of the storage node n cannot autonomously return to the low level. Therefore, the data stored in the selected cell is destroyed.

Therefore, the potential Vwl of the word lines WL is controlled such that gradient of rising of the potential Vwl of the word lines WL to the first potential V1 is larger than gradient of further rising of the potential Vwl from the first potential V1 to the second potential V2. This makes it possible to suddenly raise the potential Vwl of the word lines WL while the storage node n is unsusceptible to the potential of the bit line BL and gently raise the potential Vwl of the word lines WL when the storage node n of the bit line BL becomes susceptible to the potential of the bit line BL.

Therefore, it is possible to improve stability during the readout of data without fixing the potential Vwl of the word lines WL to low potential during a predetermined period until the potentials of the storage nodes n and nb are stabilized during the readout of data. It is possible to suppress destruction of the data stored in the memory cells 12 without lowering an operating frequency.

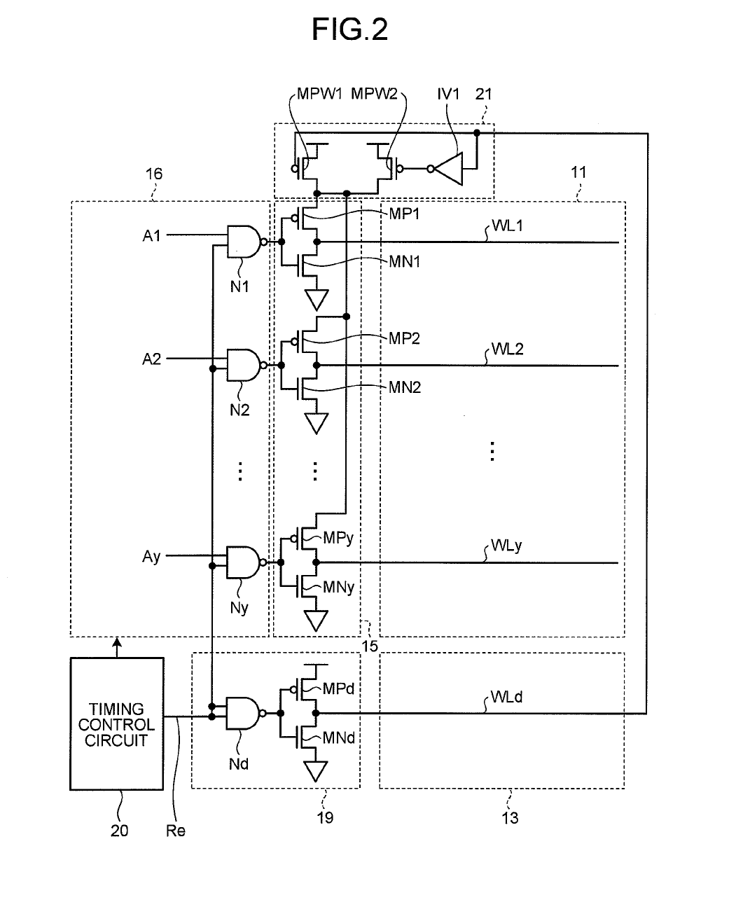

FIG. 2 is a block diagram of the schematic configurations of the driver 15 and the word-line-potential control circuit 21 shown in FIG. 1.

In FIG. 2, P-channel field effect transistors MP1 to MPy and N-channel field effect transistors MN1 to MNy are provided in the driver 15. The P-channel field effect transistors MP1 to MPy and the N-channel field effect transistors MN1 to MNy are respectively formed as pairs to configure y inverters. Connection points of drains of the P-channel field effect transistors MP1 to MPy and drains of the N-channel field effect transistors MN1 to MNy are respectively connected to the word lines WL1 to WLy.

The dummy driver 19 includes a P-channel field effect transistor MPd, an N-channel field effect transistor MNd and a NAND circuit Nd. The P-channel field effect transistor MPd and the N-channel field effect transistor MNd configure an inverter. A connection point of a drain of the P-channel field effect transistor MPd and a drain of the N-channel field effect transistor MNd is connected to the dummy word line WLd. An output terminal of the NAND circuit Nd is connected to a connection point of a gate of the P-channel field effect transistor MPd and a gate of the N-channel field effect transistor MNd. A read enable signal Re for permitting readout from the memory cells 12 is input to a pair of input terminals of the NAND circuit Nd.

The row decoder 16 includes NAND circuits N1 to Ny. Output terminals of the NAND circuits N1 to Ny are respectively connected to connection points of gates of the P-channel field effect transistors MP1 to MPy and gates of the N-channel field effect transistors MN1 to MNy. Row selection signals A1 to Ay for selecting the word lines WL1 to WLy are input to one input terminals of the NAND circuits N1 to Ny. The read enable signal Re is input to the other input terminals of the NAND circuits N1 to Ny.

The word-line-potential control circuit 21 includes P-channel field effect transistors MPW1 and MPW2 and an inverter IV1. The P-channel field effect transistor MPW1 can set driving force larger than that of the P-channel field effect transistor MPW2. Sources of the P-channel field effect transistors MPW1 and MPW2 are connected to power supply potential. Drains of the P-channel field effect transistors MPW1 and MPW2 are connected to sources of the P-channel field effect transistors MP1 to MPy. A gate of the P-channel field effect transistor MPW1 is connected to the dummy word line WLd. A gate of the P-channel field effect transistor MPW2 is connected to the dummy word line WLd via the inverter IV1.

The timing control circuit 20 can output the read enable signal Re to the NAND circuits N1 to Ny and Nd.

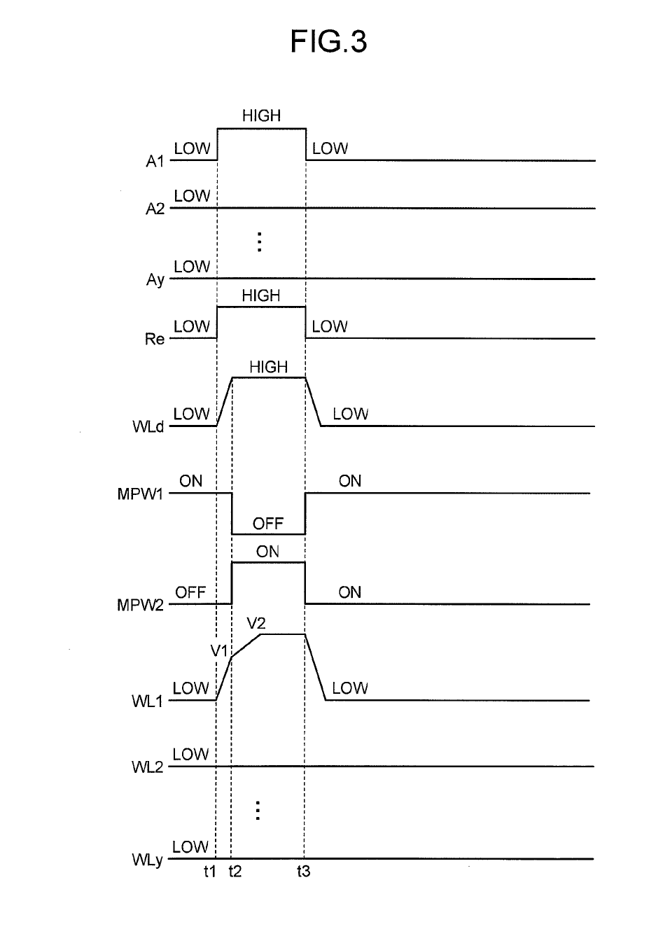

FIG. 3 is a timing chart of signal waveforms of the units shown in FIG. 2.

In FIG. 3, before readout from the memory cells 12 is performed, the read enable signal Re is maintained at a low level. When the read enable signal Re is maintained at the low level, an output of the NAND circuit Nd changes to a high level, the P-channel field effect transistor MPd is turned off, and the N-channel field effect transistor MNd is turned on.

When the N-channel field effect transistor MNd is turned on, the dummy word line WLd is connected to the ground potential and the dummy word line WLd is maintained at the low level. When the dummy word line WLd is maintained at the low level, the P-channel field effect transistor MPW1 is turned on, the P-channel field effect transistor MPW2 is turned off, and electric power is supplied to the sources of the P-channel field effect transistors MP1 to MPy via the P-channel field effect transistor MPW1.

For example, if the word line WL1 among the word lines WL1 to WLy is selected, the timing control circuit 20 changes the read enable signal Re from the low level to the high level and the row decoder 16 changes a row selection signal A1 from the low level to the high level (t1).

When the row selection signal A1 and the read enable signal Re changes from the low level to the high level, the output of the NAND circuit N1 changes from the high level to the low level, the P-channel field effect transistor MP1 is turned on, and the N-channel field effect transistor MN1 is turned off.

When the P-channel field effect transistor MP1 is turned on, the word line WL1 is connected to the power supply potential via the P-channel field effect transistor MPW1 and the word line WL1 is raised from the low level to the first potential V1 according to the driving force of the P-channel field effect transistor MPW1 (t2).

When the read enable signal Re changes from the low level to the high level, the output of the NAND circuit Nd changes from the high level to the low level, the P-channel field effect transistor MPd is turned on, and the N-channel field effect transistor MNd is turned off.

When the P-channel field effect transistor MPd is turned on, the dummy word line WLd is connected to the power supply potential and the dummy word line WLd is changed from the low level to the high level (t2).

When the dummy word line WLd is changed from the low level to the high level, the P-channel field effect transistor MPW1 is turned off, the P-channel field effect transistor MPW2 is turned on, and electric power is supplied to the sources of the P-channel field effect transistors MP1 to MPy via the P-channel field effect transistor MPW2.

When electric power is supplied to the sources of the P-channel field effect transistors MP1 to MPy via the P-channel field effect transistor MPW2, the word line WL1 is raised from the first potential V1 to the second potential V2 according to the driving force of the P-channel field effect transistor MPW2 (t2).

When the word line WL1 is raised from the first potential V1 to the second potential V2, data is read out from a selected cell connected to the word line WL1.

When the data is read out from the selected cell, the row selection signal A1 and the read enable signal Re are changed from the high level to the low level (t3). When the row selection signal A1 and the read enable signal Re are changed from the high level to the low level, the potentials of the word line WL1 and the dummy word line WLd are changed from the high level to the low level. The P-channel field effect transistor MPW1 is turned on and the P-channel field effect transistor MPW2 is turned off.

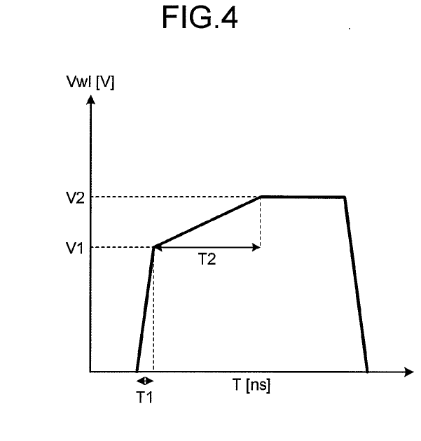

FIG. 4 is a diagram of a waveform of the potential of the word lines WL shown in FIG. 1 during readout of data.

In FIG. 4, the P-channel field effect transistor MPW1 shown in FIG. 2 can set gradient of rising of the potential Vwl of the word lines WL to the first potential V1 larger than gradient of rising of the potential Vwl from the first potential V1 to the second potential V2.

For example, if the potential of the storage node n shown in FIG. 1 is at the low level and the potential of the storage node nb shown in FIG. 1 is at the high level, time until the potential Vwl of the word lines WL rises to the first potential V1 is desirably set such that a rise in the potential of the storage node n at the time when the transfer transistor F1 is turned on can autonomously return to an original level.

It is possible to adjust gradient during rising of the potential Vwl of the word line WL1 to the first potential V1 (V1/T1) and gradient during rising of the potential Vwl of the word line WL1 from the second first potential V1 to the second potential V2 ((V2−V2)/T2) by adjusting the driving forces of the P-channel field effect transistors MPW1 and MPW2. Time T1 in which the potential Vwl of the word line WL1 rises from the ground potential to the first potential V1 is desirably set to be equal to or shorter than 50% of time T2 in which the potential Vwl of the word line WL1 rises from the ground potential to the second potential V2 and more desirable set to be equal to or shorter than 20% of the time T2.

It is possible to adjust the time T2 during rising of the potential Vwl of the word line WL1 from the first potential V1 to the second potential V2 by adjusting the number of dummy cells 14 connected to the dummy word line WLd. For example, the number of dummy cells 14 connected to the dummy word lines WLd can be set to a half of the number of memory cells 12 connected to any one word line WL among the word lines WL1 to WLy.

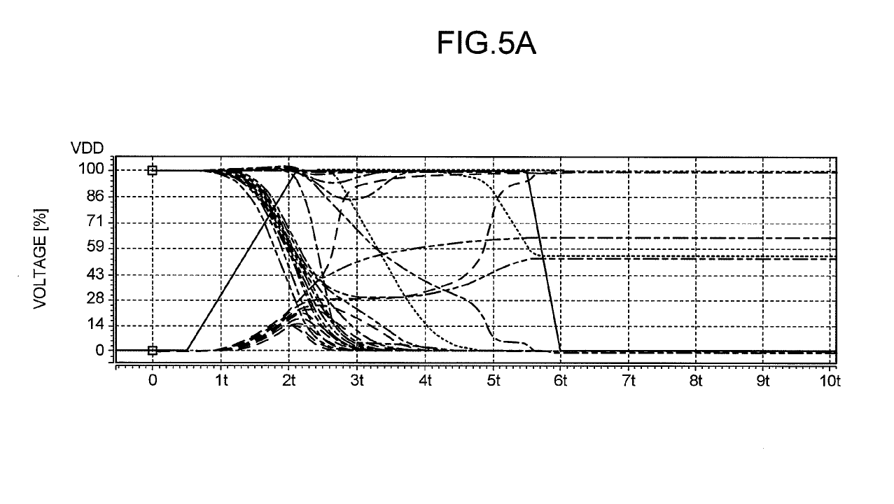

FIGS. 5A and 5B are diagrams of simulation waveforms of the potentials of the storage nodes n and nb shown in FIG. 1 during the readout of data compared with an example in the past.

In FIGS. 5A and 5B, it is assumed that the potential of the storage node n of the memory cell 12 shown in FIG. 1 is at the low level and the potential of the storage node nb of the memory cell 12 is at the high level. During readout of the data from the selected cell, the bit lines BL and BLB are pre-charged and the potentials of the bit lines BL and BLB change to the high level.

As shown in FIG. 5A, for example, if the potential Vwl of the word lines WL is suddenly raised at fixed gradient from 0 volt to 700 millivolts, the potential of the storage node n is suddenly raised from the low level to the high level. A rise in the potential of the storage node n at that point increases. When the rise in the potential of the storage node n increases to be equal to or higher than a certain degree, in some case, the potentials of the storage nodes n and nb are inverted and data stored in the selected cell is destroyed.

On the other hand, as shown in FIG. 5B, for example, after the potential Vwl of the word lines WL is suddenly raised at fixed gradient from 0 volt to 450 millivolts, if the potential Vwl of the word lines WL is gently raised at fixed gradient from 450 millivolts to 700 millivolts, the rise in the potential of the storage node n at that point decreases. Therefore, even when the low-level storage node n is connected to the high-level bit line BL during the readout of data from the memory cell 12, it is possible to prevent the potentials of the storage nodes n and nb from being inverted and prevent the data stored in the selected cell from being broken.

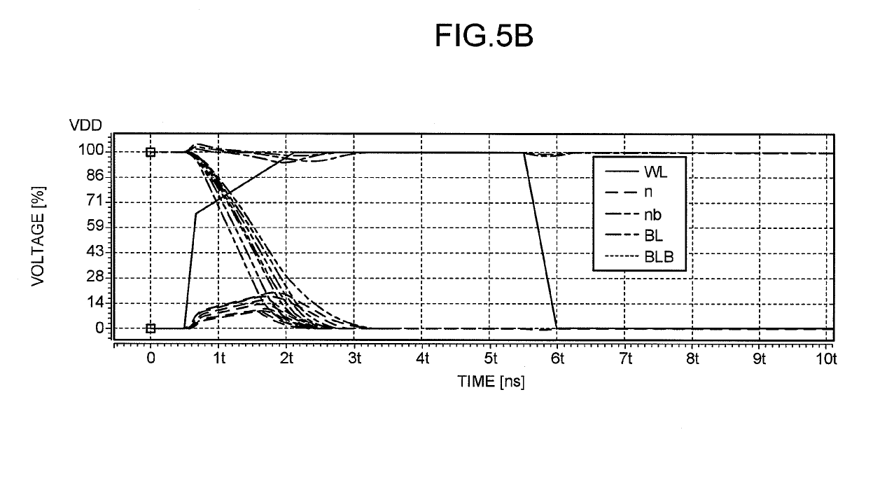

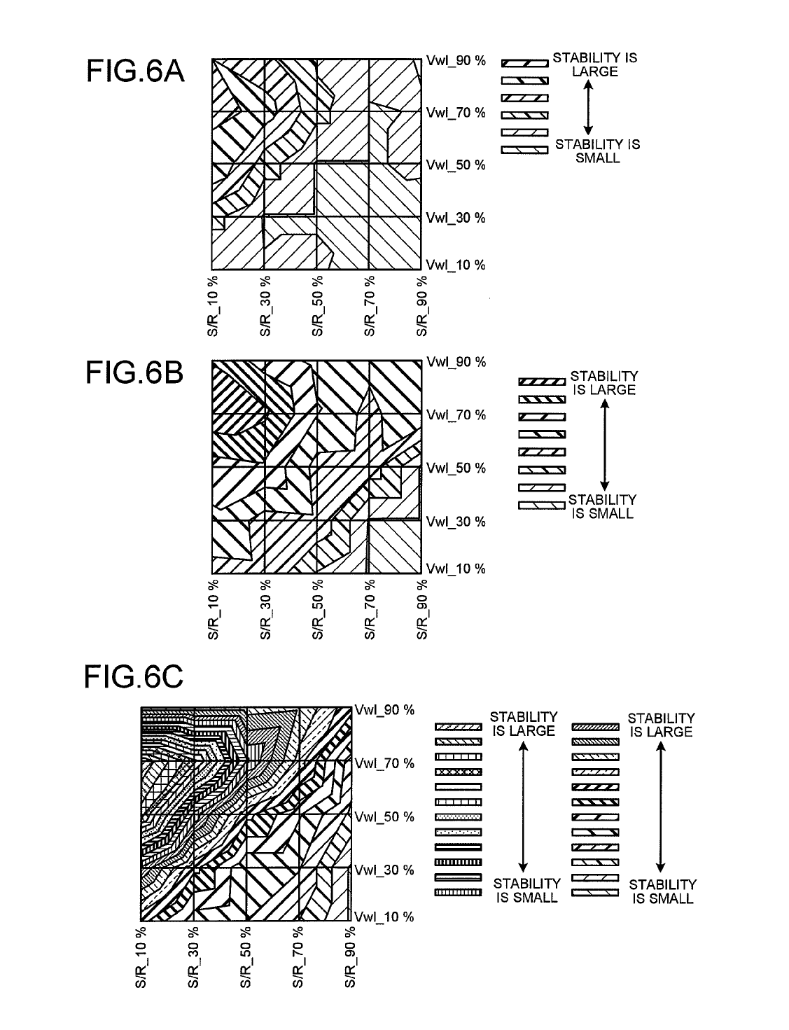

FIGS. 6A to 6C are diagrams of changes in a Z value that occur when the first rising time T1 and the first rising voltage V1 shown in FIG. 4 are changed. FIGS. 7A and 7B are enlarged diagrams of a part of FIG. 6C.

In FIG. 6A, in the case of the example in the past shown in FIG. 5A, when a through rate S/R was set such that rising time was set to 0.4 nanosecond, the Z value was 4.6. On the other hand, in the embodiment shown in FIG. 5B, when the through rate S/R was set such that rising time T1+T2 shown in FIG. 4 was set to 0.4 nanoseconds, the Z value could be increased to about 4.7 to 4.8 by setting the rising time T1 to be equal to or shorter than 30% of the rising time T1+T2 and setting a ratio of the first potential V1 to the second potential V2 to 50% or higher. The Z value is an index indicating stability during the readout of data from the memory cell 12.

In FIG. 6B, in the case of the example in the past shown in FIG. 5A, when the through rate S/R was set such that rising time was set to 0.8 nanosecond, the Z value was 4.7. On the other hand, in the embodiment shown in FIG. 5B, when the through rate S/R was set such that rising time T1+T2 shown in FIG. 4 was set to 0.8 nanosecond, the Z value could be increased to about 4.8 to 4.95 by setting the rising time T1 to be equal to or shorter than 40% of the rising time T1+T2 and setting the ratio of the first voltage V1 to the second voltage V2 to 50% or higher. In particular, the Z value could be increased to about 4.9 to 4.95 by setting the rising time T1 to be equal to or smaller than 20% of the rising time T1+T2 and setting the ratio of the first potential V1 to the second potential V2 to about 60% to 80%.

In FIG. 6C, in the case of the example in the past shown in FIG. 5A, when the through rate S/R was set such that rising time was set to 1.6 nanoseconds, the Z value was 4.9. On the other hand, in the embodiment shown in FIG. 5B, when the through rate S/R was set such that the rising time T1+T2 shown in FIG. 4 was set to 1.6 nanoseconds, the Z value could be increased to about 5.6 to 5.75 by setting the rising time T1 to be equal to or shorter than 20% of the rising time T1+T2 and setting the ratio of the first potential V1 to the second potential V2 to about 60% to 70%. In particular, as shown in FIG. 7, the Z value could be increased to about 5.8 to 5.9 by setting the rising time T1 to be equal to or shorter than 10% of the rising time T1+T2 and setting the ratio of the first potential V1 to the second potential V2 to about 60% to 70%.

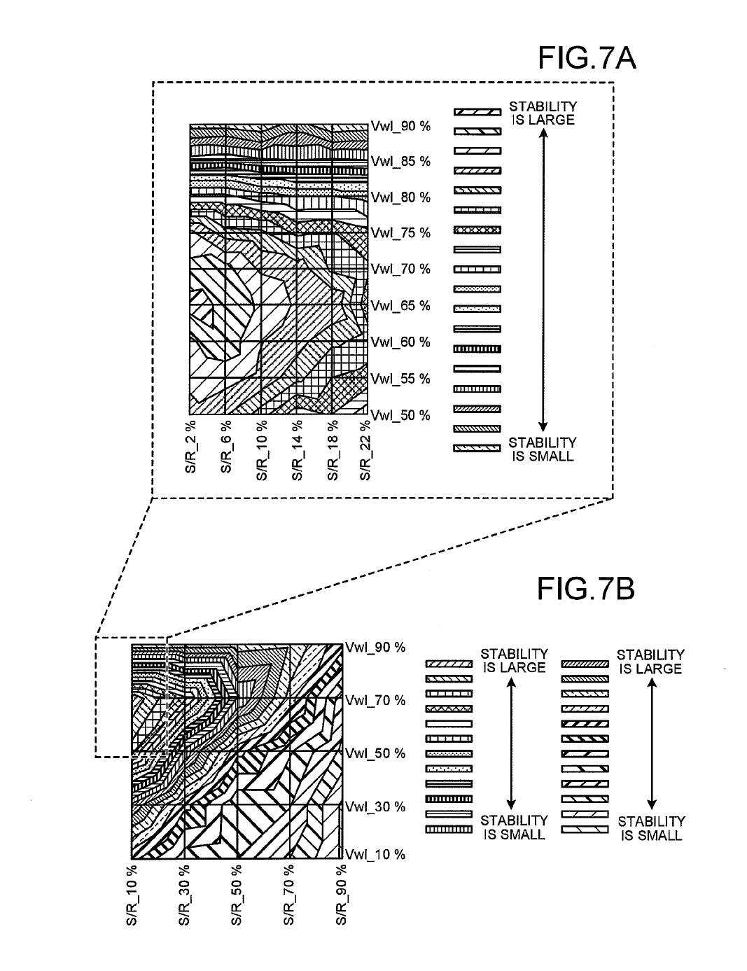

FIG. 8 is a diagram of changes in the Z value that occur when the through rate S/R is changed. S1 indicates the Z value in the example in the past shown in FIG. 5A. S2 is a Z value obtained when the rising time T1+T2 of the potential Vwl of the word lines WL was set to 0.4 nanosecond in the embodiment shown in FIG. 5B. S3 indicates the Z value obtained when the rising time T1+T2 of the potential Vwl of the word lines WL in the embodiment shown in FIG. 5B was set to 0.8 nanosecond. S4 indicates the Z value obtained when the rising time T1+T2 of the potential Vwl of the word lines WL in the embodiment shown in FIG. 5B was set to 1.6 nanoseconds.

In FIG. 8, in the embodiment shown in FIG. 5B, the Z value can be increased compared with the example in the past shown in FIG. 5A. The Z value can be increased by increasing the rising time T1+T2 of the potential Vwl of the word lines WL.

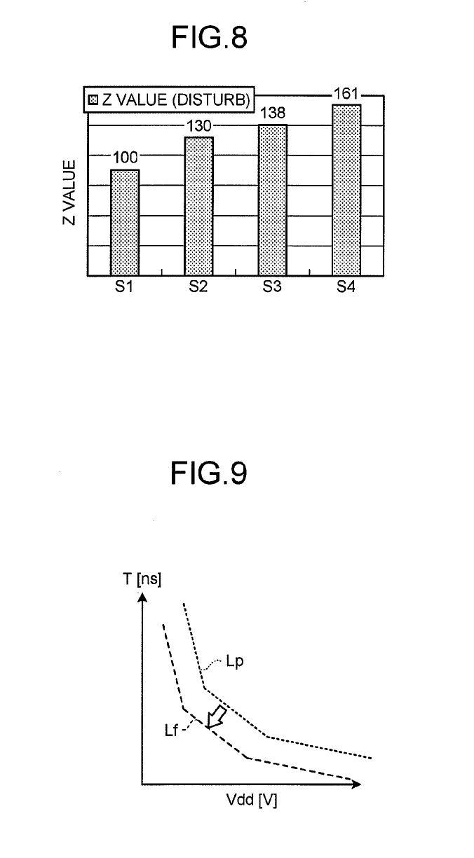

FIG. 9 is a graph of a relation between power supply voltage and operation time and percentage defectives during the readout of data.

In FIG. 9, when power supply potential Vdd and the rising time T of the potential Vwl of the word lines WL decrease, percentage defectives due to disturb during the readout of data increase. In the example in the past shown in FIG. 5A, a boundary between a non-defective product and a defective product with the power supply potential Vdd and the rising time T set as parameters is represented as Lp. On the other hand, in the embodiment shown in FIG. 5B, a boundary between a non-defective product and a defective product with the power supply potential Vdd and the rising time T set as parameters is represented as Lf. Therefore, it is possible to realize a reduction in power supply voltage and an increase in speed of readout operation without worsening percentage defectives due to disturb during the readout of data.

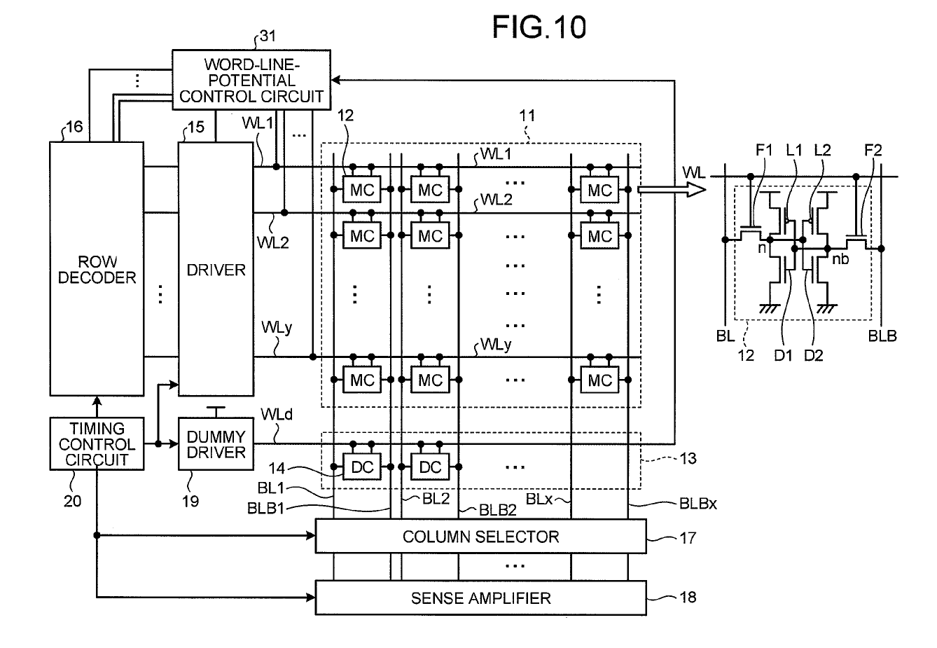

FIG. 10 is a block diagram of the schematic configuration of a semiconductor storage device according to a second embodiment of the present invention.

In FIG. 10, the semiconductor storage device includes a word-line-potential control circuit 31 instead of the word-line-potential control circuit 21 shown in FIG. 1.

The word-line-potential control circuit 31 can control the potential Vwl of the word lines WL such that, during readout of data from the memory cells 12, gradient of rising of the potential Vwl of the word lines WL to the first potential V1 is larger than gradient of further rising of the potential Vwl from the first potential V1 to the second potential V2. The word-line-potential control circuit 31 can control rising gradient of the potential Vwl of the word lines WL by directly controlling the potential Vwl of the word lines WL. The first potential V1 can be set to threshold voltage of the transfer transistors F1 and F2.

When data is read out from a selected cell, the column selector 17 performs column selection. The selected bit lines BL1 to BLx and BLB1 to BLBx are pre-charged. The row decoder 16 performs row selection. The driver 15 and the word-line-potential control circuit 31 drive the selected word lines WL1 to WLy. The dummy driver 19 drives the dummy word line WLd.

When the selected word lines WL1 to WLy are driven by the driver 15 and the word-line-potential control circuit 31, the potential Vwl of the word lines WL1 to WLy rises according to the driving forces of the driver 15 and the word-line-potential control circuit 31. When the dummy word line WLd is driven by the dummy driver 19, the potential Vwld of the word lines WL1 to WLy rises to the first potential V1 according to the driving force of the dummy driver 19.

The parasitic capacitance of the dummy word line WLd is smaller than the parasitic capacitance of the word lines WL1 to WLy. Therefore, the potential Vwld of the dummy word line WLd rises quicker than the potential Vwl of the word lines WL1 to WLy.

When the potential Vwld of the dummy word line WLd rises quicker than the potential Vwl of the selected word lines WL1 to WLy, the word-line-potential control circuit 31 interrupts the power supply to the driver 15 when the potential Vwl of the word lines WL1 to WL2 rises to the first potential V1. When the power supply to the driver 15 is interrupted by the word-line-potential control circuit 31, the potential Vwl of the word lines WL1 to WLy further rises from the first potential V1 to the second potential V2 at gradient smaller than gradient at which the potential Vwl of the word lines WL1 to WLy rises to the first potential V1.

When the potential Vwl of the word lines WL1 to WLy further rises to the second potential V2, the transfer transistors F1 and F2 enter a saturated region and the storage nodes n and nb conduct with the bit lines BL1 to BLx and BLB1 to BLBx. When the storage nodes n and nb conduct with the bit lines BL1 to BLx and BLB1 to BLBx, the potentials of the bit lines BL1 to BLx and BLB1 to BLBx change according to the potentials of the storage nodes n and nb and are amplified by the sense amplifier 18.

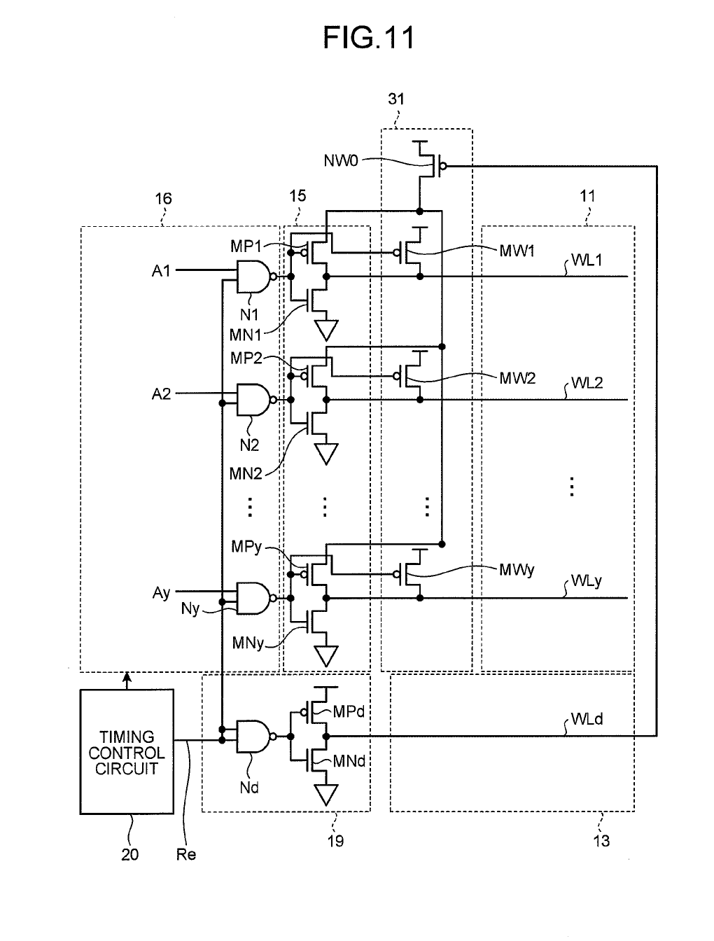

FIG. 11 is a block diagram of the schematic configurations of the driver 15 and the word-line-potential control circuit 31 shown in FIG. 10.

In FIG. 11, the word-line-potential control circuit 31 includes P-channel field effect transistors MW0 to MWy. Sources of the P-channel field effect transistors MW0 to MWy are connected to power supply potential. A drain of the P-channel field effect transistor MW0 is connected to sources of the P-channel field effect transistors MP1 to MPy. A gate of the P-channel field effect transistor MW0 is connected to the dummy word line WLd.

Drains of the P-channel field effect transistors MW1 to MWy are respectively connected to the word lines WL1 to WLy. Gates of the P-channel field effect transistors MW1 to MWy are respectively connected to the output terminals of the NAND circuits N1 to Ny.

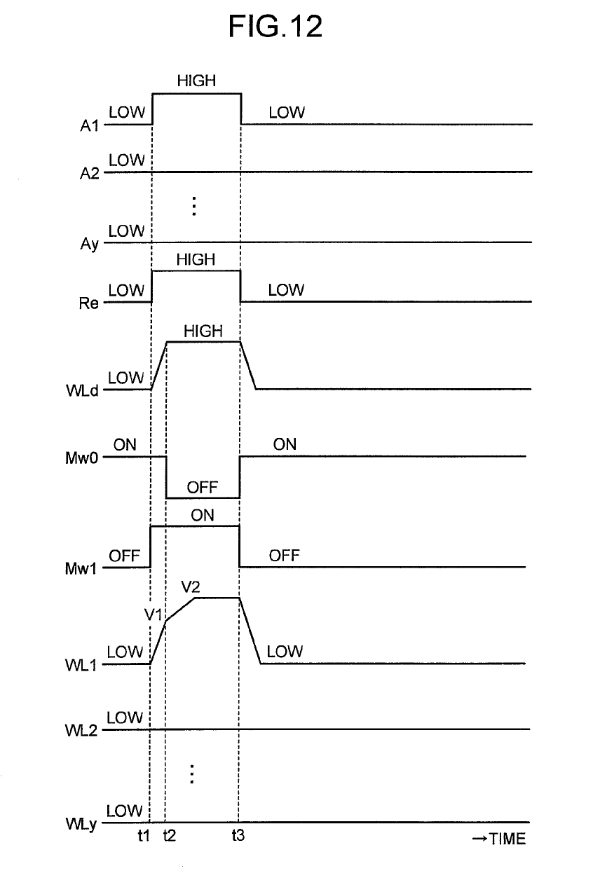

FIG. 12 is a timing chart of signal waveforms of the units shown in FIG. 11.

In FIG. 12, before readout from the memory cells 12 is performed, the read enable signal Re is maintained at a low level. When the read enable signal Re is maintained at the low level, an output of the NAND circuit Nd changes to a high level, the P-channel field effect transistor MPd is turned off, and the N-channel field effect transistor MNd is turned on.

When the N-channel field effect transistor MNd is turned on, the dummy word line WLd is connected to the ground potential and the dummy word line WLd is maintained at the low level. When the dummy word line WLd is maintained at the low level, the P-channel field effect transistor MW0 is turned on and electric power is supplied to the sources of the P-channel field effect transistors MP1 to MPy via the P-channel field effect transistor MW0.

For example, if the word line WL1 among the word lines WL1 to WLy is selected, the timing control circuit 20 changes the read enable signal Re from the low level to the high level and the row decoder 16 changes the row selection signal A1 from the low level to the high level (t1).

When the row selection signal A1 and the read enable signal Re change from the low level to the high level, the output of the NAND circuit N1 changes from the high level to the low level, the P-channel field effect transistors MP1 and MW1 are turned on, and the N-channel field effect transistor MN1 is turned off.

When the P-channel field effect transistors MP1 and MW1 are turned on, the word line WL1 is connected to the power supply potential via the P-channel field effect transistor MW0, the word line WL1 is connected to the power supply potential via the P-channel field effect transistor MW1, and the word line WL1 is raised from the low level to the first potential V1 according to the driving forces of the P-channel field effect transistor MP1 and MW1 (t2).

When the read enable signal Re changes from the low level to the high level, the output of the NAND circuit Nd changes from the high level to the low level, the P-channel field effect transistor MPd is turned on, and the N-channel field effect transistor MNd is turned off.

When the P-channel field effect transistor MPd is turned on, the dummy word line WLd is connected to the power supply potential and the dummy word line WLd is changed from the low level to the high level (t2).

When the dummy word line WLd is changed from the low level to the high level, the P-channel field effect transistor MW0 is turned off. Therefore, the driving of the word line WL1 by the P-channel field effect transistor MP1 is interrupted and the word line WL1 is raised from the first potential V1 to the second potential V2 according to the driving force of the P-channel field effect transistor MW1 (t2).

When the word line WL1 is raised from the first potential V1 to the second potential V2, data is read out from a selected cell connected to the word line WL1.

When the data is read out from the selected cell, the row selection signal A1 and the read enable signal Re are changed from the high level to the low level (t3). When the row selection signal A1 and the read enable signal Re are changed from the high level to the low level, the potentials of the word line WL1 and the dummy word line WLd are changed from the high level to the low level. The P-channel field effect transistor MW0 is turned on and the P-channel field effect transistor MW1 is turned off.

In the embodiment, a method of adjusting gradient during rising of the potential Vwl of the word lines WL to change in a gentle direction in two stages is explained. However, the gradient during rising of the potential Vwl of the word lines WL can be adjusted to sequentially change in a gentle direction in three or more stages.

In the embodiment, a method of adjusting, to adjust the time T2 in which the potential Vwl of the word line WL1 rises from the first potential V1 to the second potential V2, the number of dummy cells 14 connected to the dummy word line WLd is explained. However, it is also possible to connect variable capacitance to the dummy word line WLd and control the parasitic capacitance of the dummy word line WLd with information concerning global fluctuation in an SRAM. For example, it is also possible to provide a monitor circuit that monitors threshold voltage or leak current of the transfer transistors F1 and F2 shown in FIG. 1 and control, based on the monitoring, the parasitic capacitance of the dummy word line WLd.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the sprit of the inventions. The accompanying claims and their equivalents are intended to cover such forms or modifications as would fall within the scope and spirit of the inventions.

What is claimed is:

1. A semiconductor storage device comprising:
a memory cell array comprising memory cells in a matrix in a row direction and a column direction;
word lines configured to select a row for the memory cell array during readout of data;
a driver configured to drive the word lines; and
a word-line-potential controller configured to control potential of the word lines in such a manner that, during the readout of data, a gradient of a first rise of a potential of the word lines to a first potential is larger than a gradient of a second rise of the potential from the first potential to a second potential.

2. The semiconductor storage device of claim 1, wherein the word-line-potential controller is configured to control a driving force of a power supply to the driver in order to control the gradient of the first rise of the potential of the word lines to the first potential and the gradient of the second rise of the potential from the first potential to the second potential.

3. The semiconductor storage device of claim 2, wherein
the driver comprises an inverter in each word line; and
the word-line-potential controller comprises:
a first field effect transistor configured to supply electric power to the inverter until the potential of the word line becomes substantially equal to the first potential; and
a second field effect transistor configured to supply electric power to the inverter after the potential of the word line becomes substantially equal to the first potential, the second field effect transistor comprising a driving force smaller than a driving force of the first field effect transistor.

4. The semiconductor storage device of claim 3, further comprising:
a dummy word line connected to dummy cells smaller in number than a number of memory cells connected to the word lines; and
a dummy driver configured to drive the dummy word line when driving any one word line among the word lines of the memory cell array, wherein
gate potentials of the first and second field effect transistors are controlled based on a potential of the dummy word line.

5. The semiconductor storage device of claim 4, wherein
each memory cell comprises:
a first Complementary Metal Oxide Semiconductor (CMOS) inverter comprising a first driving transistor and a first load transistor connected in series to each other;
a second CMOS inverter comprising a second driving transistor and a second load transistor connected in series to each other;
a first transfer transistor connected between a first node and a first bit line, the first node being provided at a connection point of the first driving transistor and the first load transistor; and
a second transfer transistor connected between a second storage node and a second bit line, the second storage node being provided at a connection point of the second driving transistor and the second load transistor,
wherein outputs and inputs of the first CMOS inverter and the second CMOS inverter are cross-coupled to each other, and
wherein a gate of the first transfer transistor and a gate of the second transfer transistor are connected to the word lines.

6. The semiconductor storage device of claim 5, wherein the first potential is a threshold voltage of the first and second transfer transistor.

7. The semiconductor storage device of claim 6, wherein the second potential is a power supply potential.

8. The semiconductor storage device of claim 5, wherein a potential of the first storage node is at a low level, and a potential of the second storage node is at a high level, a time until a potential of the word lines becomes substantially equal to the first potential is set in such a manner that a rise in the potential of the first storage node at the time when the first transfer transistor is turned on is equal to or smaller than a value that causes the potential of the first storage node autonomously return to an original level, when the bit line is to be pre-charged before readout of data from a selected cell.

9. The semiconductor storage device of claim 8, wherein a time for the potential of the word lines to rise from a ground potential to the first potential is equal to or smaller than 50% of a time for the potential of the word line to rise from the ground potential to the second potential.

10. The semiconductor storage device of claim 1, wherein the word-line-potential controller is configured to control a potential of the word lines in order to control a gradient of a first rise of the potential of the word lines to the first potential and gradient of a second rise of the potential from the first potential to the second potential.

11. The semiconductor storage device of claim 10, wherein
the driver comprises an inverter in each word line; and
the word-line-potential controller comprises:
a first field effect transistor connected in parallel to a P-channel field effect transistor of the inverter and switched to be ON/OFF when the P-channel field effect transistor is turned ON/OFF; and
a second field effect transistor configured to interrupt the power supply to the inverter after the potential of the word lines becomes substantially equal to the first potential.

12. The semiconductor storage device of claim 11, further comprising:
a dummy word line connected to dummy cells smaller in number than a number of memory cells connected to the word lines; and
a dummy driver configured to drive the dummy word line when driving any one word line among the word lines of the memory cell array, wherein
gate potential of the second field effect transistor is controlled based on a potential of the dummy word line.

13. The semiconductor storage device of claim 12, wherein
each memory cell comprises:
a first CMOS inverter comprising a first driving transistor and a first load transistor connected in series to each other;
a second CMOS inverter comprising a second driving transistor and a second load transistor connected in series to each other;
a first transfer transistor connected between a first node and a first bit line, the first node being provided at a connection point of the first driving transistor and the first load transistor; and
a second transfer transistor connected between a second storage node and a second bit line, the second storage node being provided at a connection point of the second driving transistor and the second load transistor,
wherein outputs and inputs of the first CMOS inverter and the second CMOS inverter are cross-coupled to each other, and
wherein a gate of the first transfer transistor and a gate of the second transfer transistor are connected to the word lines.

14. The semiconductor storage device of claim 13, wherein the first potential is a threshold voltage of the first and second transfer transistor.

15. The semiconductor storage device of claim 14, wherein the second potential is a power supply potential.

16. The semiconductor storage device of claim 13, wherein a potential of the first storage node is at a low level, and a potential of the second storage node is at a high level, a time until a potential of the word lines becomes substantially equal to the first potential is set in such a manner that a rise in the potential of the first storage node at the time when the first transfer transistor is turned on is equal to or smaller than a value that causes the potential of the first storage node to autonomously return to an original level, when the bit line is to be pre-charged before readout of data from a selected cell.

17. The semiconductor storage device of claim 16, wherein a time for the potential of the word lines to rise from a ground potential to the first potential is equal to or smaller than 50% of a time for the potential of the word line to rise from the ground potential to the second potential.

18. A method of controlling a word line potential comprising:
increasing a potential of word lines for row selection during readout of data from memory cells to a first potential; and
increasing the potential of the word lines from the first potential to second potential at a gradient smaller than a gradient during the increase of the potential of the word lines to the first potential while reading out data from the memory cells.

19. The method of controlling a word line potential of claim 18, wherein
each memory cell comprises:
a first CMOS inverter comprising a first driving transistor and a first load transistor connected in series to each other;
a second CMOS inverter comprising a second driving transistor and a second load transistor connected in series to each other;
a first transfer transistor connected between a first node and a first bit line, the first node being provided at a connection point of the first driving transistor and the first load transistor; and
a second transfer transistor connected between a second storage node and a second bit line, the second storage node being provided at a connection point of the second driving transistor and the second load transistor,
wherein outputs and inputs of the first CMOS inverter and the second CMOS inverter cross-coupled to each other, and
wherein a gate of the first transfer transistor and a gate of the second transfer transistor are connected to the word lines.

20. The method of controlling word line potential of claim 19, wherein a potential of the first storage node is at a low level, and a potential of the second storage node is at a high level, a time until a potential of the word lines becomes substantially equal to the first potential is set in such a manner that a rise in the potential of the first storage node at the time when the first transfer transistor is turned on is equal to or smaller than a value that causes the potential of the first storage node to autonomously return to an original level, when the bit line is to be pre-charged during readout of data from a selected cell.
